(19) United States
(12) Patent Application Publication
(10) Pub. No.: US 2004/0164309 A1
(43) Pub. Date: Aug. 26, 2004

(54) Semiconductor laser device, method for controlling semiconductor laser, and image display device

(75) Inventors: Hideaki Okano, Saitama-ken (JP); Tooru Sugiyama, Saitama-ken (JP); Toshitaka Yamada, Tokyo (JP)

Correspondence Address: FOLEY & LARDNER, 2029 CENTURY PARK EAST, SUITE 3500, LOS ANGELES, CA, 90067

(73) Assignee: KABUSHIKI KAISHA TOSHIBA

(21) Appl. No.: 10/724,567

(22) Filed: Nov. 26, 2003

(30) Foreign Application Priority Data
Nov. 29, 2002 (JP) 2002-348709

(51) Int. Cl. H01L 33/00

(52) U.S. Cl. 257/98

(57) ABSTRACT

Among light emitted from a semiconductor laser, light emitted within a predetermined angle θx with respect to the z-axis in the direction of the slow axis (x-axis) is returned by a plane mirror to the semiconductor laser to enhance the intensity of the laser light emitted by the semiconductor device using external resonance.

### CROSS-REFERENCE TO RELATED APPLICATIONS

This application is based upon and claims the benefit of priority from the prior Japanese Patent Application No. 2002-348709, filed Nov. 29, 2002, the entire contents of which are incorporated herein by reference.

### BACKGROUND OF THE INVENTION

1. Field of the Invention

The present invention relates to a semiconductor laser device of an external resonator type and a method for controlling a semiconductor laser. The present invention also concerns a projection image display device using the semiconductor laser device as a light source.

2. Description of the Related Art

Recently, attempts have been made to use a semiconductor laser as a light source of a projection image display device such as a liquid crystal projector.

The technique of using a semiconductor laser as a light source of a projection image display device is, however, still under development: at present, it has not attained a sufficient practical utility from various points of view.

Specifically, it is desirable to use an edge emitting semiconductor laser used for this type of light source because of its high output, easy availability, and a low price; hence, for example, it is indispensable as a laser pumping source for material processing and solid-state laser.

The semiconductor laser is required to generate optical power of as high as several W to 10 W as a light source. Therefore, its light emitting area is very long in structure and has an aspect ratio ranging from 50:1 to 500:1.

Accordingly, the light beams emitted from the light emitting area vary greatly in quality depending on their emitting directions. Generally, light emitted in the direction perpendicular to a pn-junction surface (hereinafter, referred to as a fast-axis direction) is substantially in the fundamental mode.

On the other hand, in the direction parallel to the pn-junction surface (hereinafter, referred to as a slow-axis direction), the laser oscillates in various modes because of the wide waveguide layer. Therefore, the quality of the light beams emitted along the slow axis is several tens of times lower than that emitted along the fast axis.

The light emitted from the semiconductor laser is incident on a fiber laser. The fiber laser has a laser medium doped in the core of the optical fiber to generate a laser oscillation in the optical fiber using the emitted laser light.

Specifically, light beams excited by the laser oscillation are collected in the core of the optical fiber to generate visible light with high optical density; the visible light is used for image display.

However, with the semiconductor laser in which the quality of the light beams emitted along the slow axis is extremely low, as described above, it is difficult to collect the emitted light beams. Consequently, there arises a problem that it is difficult to efficiently collect the light emitted from the semiconductor laser into the core of the small-diameter optical fiber.

Raab et al in Optics Letters, Feb. 1, 2002, vol. 27, No. 3, pp. 167-169 discloses a technique of constructing an external resonator by returning part of the light beams emitted from a laser diode to the laser diode using a reflecting mirror, thereby collecting at least a portion of the emitted light beams.

The technique disclosed in Raab, however, requires a lens for converting light beams emitted at a predetermined angle of divergence to collimated light, thus having a large number of parts, which is impractical.

### BRIEF SUMMARY OF THE INVENTION

Accordingly, the present invention has been made in view of the above problems. According to embodiments of the invention, a semiconductor laser device is provided having a semiconductor laser capable of producing external resonance with a simple structure and collecting the emitted light beams to improve the efficiency of incidence on an optical fiber and a method of controlling the semiconductor laser. According to other embodiments of the invention, there is provided an image display device using the aforementioned semiconductor laser device.

A semiconductor laser device according to an embodiment of the invention includes a semiconductor laser; and a reflection device, such as a mirror, positioned to return to the semiconductor laser light emitted from the semiconductor laser within a predetermined angle range in the direction of the slow axis.

A method for controlling a semiconductor laser, according to an embodiment of the invention, includes the step of controlling the divergence of light emitted from the semiconductor laser in the direction of the fast axis; and the step of returning light emitted within the range of a predetermined angle in the direction of the slow axis, among the controlled light, to the semiconductor laser.

An image display device according to another embodiment of the invention includes a semiconductor laser device having a reflection device to return light to the semiconductor laser which is emitted within the range of a predetermined angle in the direction of the slow axis; an optical fiber excited by the incidence of the light emitted from the semiconductor laser device; a modulation device to space-modulate the light excited by the optical fiber in accordance with an image signal; and a display unit to project and display optical power obtained from the modulation device on a screen.

With such a structure and a method, among light emitted from the semiconductor laser, light emitted along the slow axis and within a predetermined angle is returned to the semiconductor laser. Therefore, the semiconductor laser can produce external resonance with a simple structure and collect the emitted light beams to improve the efficiency of incidence on an optical fiber. This realizes a high-efficiency light source, thus providing an image display device with low electric power consumption and low manufacture cost. Moreover, in accordance with embodiments of the invention, a lens such as the lens f shown in FIG. 1 of the aforementioned Raab reference is not needed, and the mirror of embodiments of the invention is positioned at a desired distance L from the laser surface and tilted to achieve a desired divergence angle.

### BRIEF DESCRIPTION OF THE SEVERAL VIEWS OF THE DRAWING

FIG. 1 is a perspective diagram of a semiconductor laser device according to an embodiment of the present invention;

FIGS. 2A and 2B are light emitting front views of the semiconductor laser device for explaining a single stripe semiconductor laser and a multistripe semiconductor laser according to an embodiment of the present invention;

FIG. 3 is a top plan view of FIG. 1 for explaining the positional relationship between the semiconductor laser and a plane mirror according to an embodiment of the present invention;

FIGS. 4A and 4B are diagrams for explaining the divergence angle characteristic in the direction along the slow axis of light emitted from the semiconductor laser according to an embodiment of the present invention;

FIG. 5 is a diagram for explaining the structure of a fiber laser using the semiconductor laser device according to an embodiment of the present invention;

FIG. 6 is a diagram for explaining an example of an image display device using the fiber laser according to an embodiment of the present invention; and

FIG. 7 is a diagram for explaining another example of an image display device using the fiber laser according to an embodiment of the present invention.

### DETAILED DESCRIPTION OF PREFERRED EMBODIMENTS

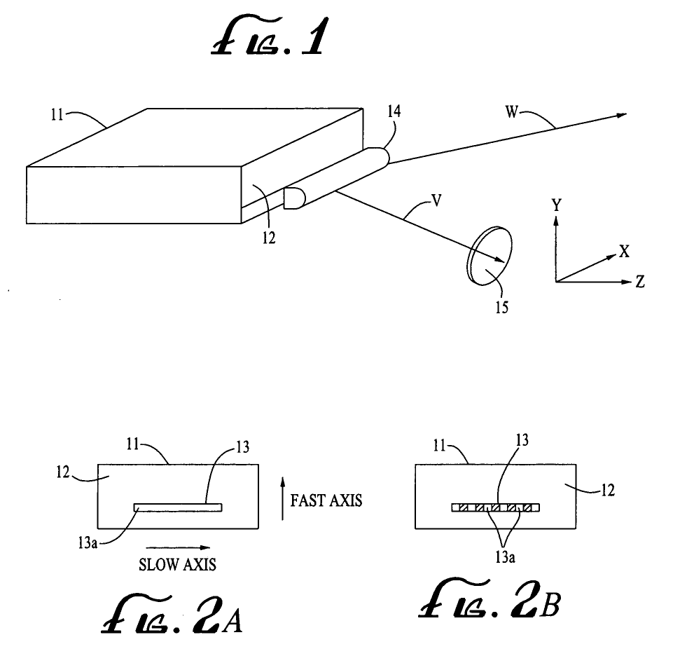

Embodiments of the present invention will be specifically described hereinafter with reference to the drawings. FIG. 1 is a schematic diagram of a semiconductor laser device according to an embodiment of the present invention. In FIG. 1, reference numeral 11 denotes a semiconductor laser.

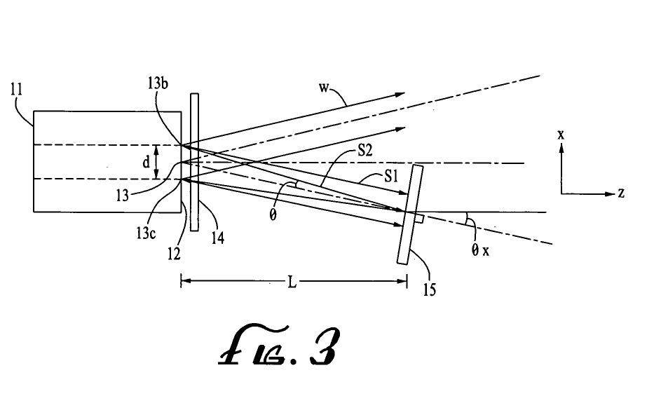

The semiconductor laser 11 is of a so-called single-stripe multimode oscillation type in which a light emitting area 13 (not shown in FIG. 1) exposed from a light emitting edge 12 is formed from one active layer 13a, as shown in FIG. 2A.

The semiconductor laser 11 may obviously be of a so-called multistripe multimode oscillation type in which a light emitting area 13 is formed of a plurality of the active layers 13a, as shown in FIG. 2B.

As an example, the light emitting area 13 of the semiconductor laser 11 may be 200 μm along the slow axis and 1.5 μm along the fast axis. The light emitting edge 12 preferably has an anti-reflective (AR) coating so as to desirably have a light reflectance of 3% or less.

In the figures, the z axis is chosen to be the direction perpendicular or normal to the light emitting edge 12, the x axis is along the slow axis direction of the light emitting area 13, and the y axis is along the fast axis direction of the light emitting area 13.

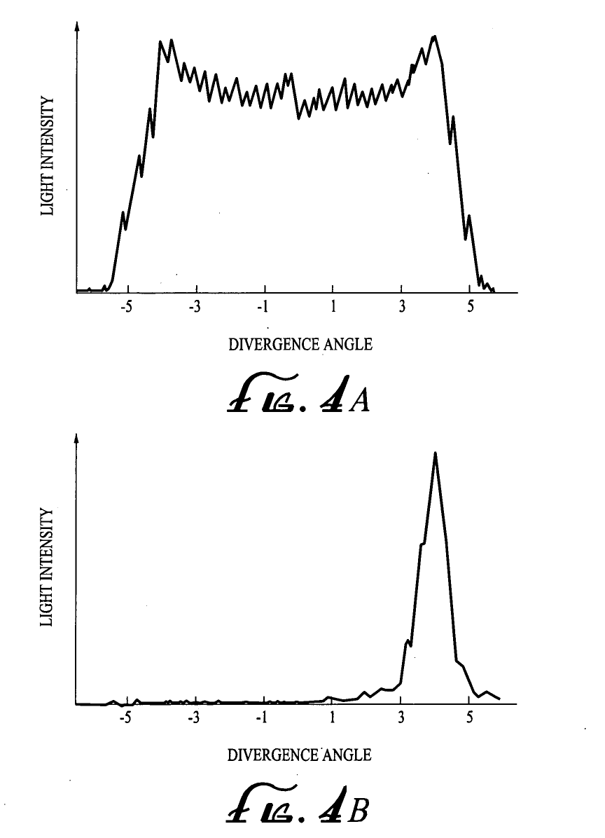

As shown in FIG. 3, the light emitted from the light emitting area 13 is collimated in the direction of the Y-axis by a collimating lens 14. The collimating lens 14 may, for example be a rod lens or a cylindrical lens having refractive power only in the direction of the Y-axis.

The light from the emitting area 13 passes though the collimating lens 14. Part of this light diverges in the direction of the x-axis at a predetermined angle relative to the z-axis, θx, and is reflected by a plane mirror 15 serving as a reflection means or a reflection device to be returned to the light emitting area 13, thus producing the desired external resonance.

In this way, as shown in FIG. 1, the light generated by the external resonance is emitted from the light emitting area 13 in the direction of w that is symmetric about the z-axis with respect to the direction v of the light that has been emitted before and reflected back to the light emitting area 13 by the plane mirror 15. The light emitted from the emitting area 13 in the direction of w is incident upon an optical fiber 18.

FIG. 3 specifically shows the positional relationship between the light emitting area 13 of the semiconductor laser 11 and the plane mirror 15. The center of the reflecting surface of the plane mirror 15 is placed a distance L apart from the light emitting edge 12 of the semiconductor laser 11.

In this case, the plane mirror 15 is arranged so that light emitted from the light emitting area 13 is perpendicularly incident thereon at a predetermined tilt angel θx (which will be described later) with respect to the z-axis in the direction of the x-axis.

When the semiconductor laser 11 performs a normal oscillation operation, the light emitted from the light emitting area 13 has a divergence angle of several degrees at a half angle with respect to the z-axis in the direction of the x-axis because of multimode oscillation.

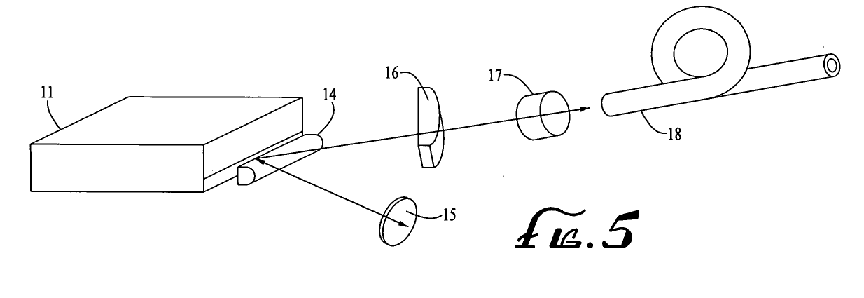

FIG. 4A shows the divergence angle characteristic in the direction of the x-axis (slow axis) of the light emitted from the light emitting area 13. The divergence angle in the direction of the x-axis with respect to the z-axis is slightly over 4 degrees at the half angle and, moreover, light with the highest light intensity is emitted in the vicinity of ±4 degrees.

Therefore, when the light emitted from the light emitting area 13 with a length of 200 μm in the direction of x-axis and having a divergence angle of as much as 4 degrees at the half angle is incident on an optical fiber (e.g., fiber 18) with a core diameter of 20 μm and an aperture of 0.3, the efficiency of incidence is given by 20×0.3/200×sin 4°=0.43; the incidence efficiency of 43 percent acts as a theoretical limit; thus, more than half of the emitted light does not enter the optical fiber.

Referring again to FIG. 3, when the plane mirror 15 is arranged to have an angle θx of −4 degrees, the external resonance is performed with light having the highest light intensity among the light emitted from the light emitting area 13.

The light collected by the external resonance is emitted at an angle of substantially +4 degrees in the direction of the x-axis that is symmetric about the z-axis with respect to light that has been emitted before from the light emitting area 13 to the plane mirror 15 and incident at a normal to the mirror 15. That is, after reflection by the mirror at approximately −4 degrees, the light from the external resonance is emitted at an angle of +4 degrees.

Here, the light that is reflected by the plane mirror 15 to return to the light emitting area 13 for external resonance is restricted by the angle at which it is emitted from the light emitting area 13.

More specifically, as shown in FIG. 3, letting d be the length of the light emitting area 13 in the direction of the x-axis (slow axis), the light is within an angle θ formed by light S1 that is emitted from a first end 13b of the light emitting area 13 to the plane mirror 15 perpendicularly thereto and light S2 that is emitted from the a second end 13c, reflected by the plane mirror 15, and returned to the first end 13b.

Considering that d [symbol] L, angle θ is expressed as:

θ=tan−1[(d/2)/L].

More specifically, among the light emitted from the light emitting area 13, light that may possibly be amplified by the external resonance has a divergence angle of θ expressed by the above expression, with respect to the light emitted to the plane mirror 15 perpendicularly thereto. For example, assuming that d=200 μm and L=5 mm, applying the above formula gives θ=1.15°.

Accordingly, the laser light amplified by the external resonance of the semiconductor laser 11 is emitted in the direction of w that is symmetric about the z-axis with respect to the optical axis of the plane mirror 15, with the divergence angle controlled to θ or less.

FIG. 4B shows the divergence angle characteristic of the emitted light in the direction of the slow axis when the external resonance by the plane mirror 15 is performed for the light emitting area 13 with a length of 200 μm in the slow-axis direction.

The divergence angle (i.e., half angle) is reduced to 1 degree as compared with the divergence angle of 4 degrees shown in FIG. 4A. That is, the divergence angle (half angle or width) of the peak shown in FIG. 4A is only one degree as compared to 4 degrees shown in FIG. 4A. For example, when the optical power is incident on the above-described optical fiber, the incidence efficiency is

20×0.3/200×sin 1°>1.

Thus, in theory, all the emitted light can be incident on the optical fiber. It is also noted that the maximum intensity of the peak shown in FIG. 4B is much higher (approximately five times higher) than the maximum intensity of the peaks shown in FIG. 4A. The width of the peak shown in FIG. 4B depends on the distance L and the larger L, the smaller the peak width.

In the above embodiment, the plane mirror 15 is used as a means or device for reflecting the light emitted from the light emitting area 13. However, a concave mirror or a convex mirror can offer the same effects. Of course, the angle θx is not limited to −4 degrees.

When the plane mirror 15 is used, the divergence angle in the direction of the slow axis is determined depending on the distance L from the light emitting edge 12. The use of the concave mirror or the convex mirror allows the divergence angle to be controlled depending on the radius of curvature. In other words, in cases where there is some practical limitation on the distance L that may be used for a particular device, the divergence angle can be controlled by optimizing the radius of curvature irrespective of the distance L.

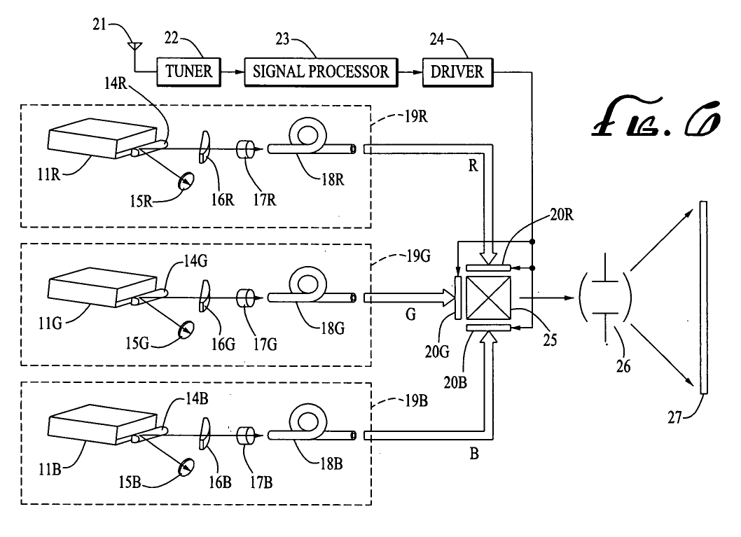

FIG. 5 shows an example of a fiber laser using the above-described semiconductor laser device. A collimating lens 16 collimates the laser light emitted from the semiconductor laser 11 only in the direction of the x-axis.

A collecting lens 17 is positioned to collect the laser beams collimated by the collimating lens 16 to pass them to the optical fiber 18. The optical fiber 18 has a core doped with a laser medium which is excited by the light emitted from the semiconductor laser 11.

As described above, external resonance of the light emitted from the semiconductor laser 11 with the plane mirror 15 provides high-quality light beams with a restricted divergence angle positioned symmetric to the direction with respect to the optical axis of the reflecting device such as the plane mirror 15.

Although the light beams are collimated only in the direction of the y-axis by the collimating lens 14, they are further collimated also in the direction of the x-axis by the collimating lens 16 and are then incident on the collecting lens 17, where they are in turn collected on the end face of the core of the optical fiber 18 by the collecting lens 17.

In such a case, most of the laser light can be incident on the optical fiber 18, as described above. The high-efficiency incident laser beams excite the laser medium in the optical fiber 18 to generate oscillation.

The use of the aforesaid semiconductor laser device provides high-efficiency fiber laser. The above described embodiments can achieve a high-efficiency up-conversion fiber laser which is particularly important for a fiber laser that obtains visible laser light from infrared light (by up-conversion) since such laser needs a high excitation-light density.

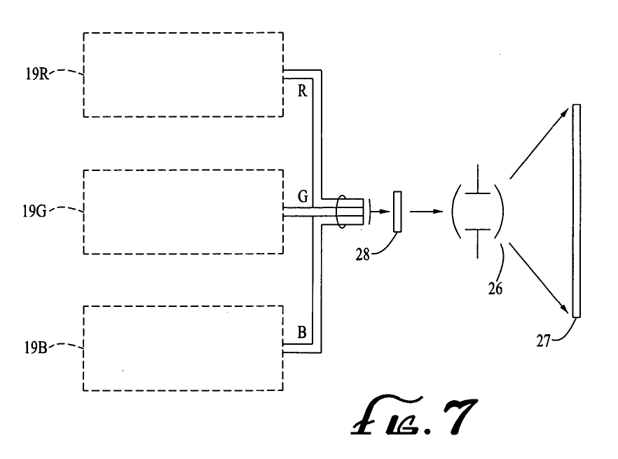

FIG. 6 shows an example of a liquid-crystal projection television (TV) receiver as an image display device using the fiber laser of FIG. 5. Reference numerals 19R, 19G, and 19B denote fiber lasers for obtaining red (R), green (G), and blue (B) emission light beams, respectively.

The fiber lasers 19R, 19G, and 19B have the same structure as that shown in FIG. 5. Therefore, the components of FIG. 6 are indicated by the numerals of FIG. 5 having suffix symbols R, G, and B, respectively.

For the fiber lasers 19R, 19G, and 19B, the rare-earth elements to be doped in optical fibers 18R, 18G, and 18B, the oscillation frequencies of the semiconductor lasers 11R, 11G, and 11B and so on are set so as to obtain R, G, B optical power, respectively.

For example, for the optical fibers 18R and 18G, Pr3+, Yb3+ and so on are used as rare-earth elements, and for the optical fiber 18B, Tm3+ and so on may be used.

The R, G, B light obtained by the fiber lasers 19R, 19G, and 19B is incident on liquid crystal panels 20R, 20G, and 20B which are disposed in correspondence with the respective light and construct a space modulation means or device.

On the other hand, a TV broadcasting signal that has been received by an antenna 21 is tuned by a tuner 22, and the image signal demodulated by a signal processor 23 is incident on the liquid crystal panels 20R, 20G, and 20B through a driver 24.

In this way, the R, G, B light rays incident on the respective liquid crystal panels 20R, 20G, and 20B are space-modulated by the image signal to be composed by a composing means or device such as a dichroic prism 25.

The composite light is projected in a magnified form on a screen 27 through a projection lens 26, and thus a TV image is displayed.

FIG. 7 shows another example of an image display device using the fiber laser of FIG. 5. Referring to FIG. 7, the same components as those of FIG. 6 are given the same reference numerals. The R, G, B light rays obtained by the fiber lasers 19R, 19G, and 19B are collected together to generate white light, seen in broad perspective (in a general view).

The white light is incident on a liquid crystal panel 28 with a color filter and subjected to space modulation, and thereafter, it is projected in an enlarged form on the screen 27 through the projection lens 26.

With such an image display device, a high-efficiency light source can be provided, thus decreasing power consumption and production cost.

It is to be understood that the present invention is not limited to the above embodiments and various modifications may be made as long as they do not depart from the gist and scope thereof.

The present invention provides, as described above, a semiconductor laser device having a semiconductor laser capable of generating external resonance with a simple structure and collecting the emitted light beams to improve the efficiency of incidence on an optical fiber and a method of controlling the semiconductor laser. The invention also provides an image display device using the semiconductor laser device.

What is claimed is:

1. A semiconductor laser device comprising:
a semiconductor laser having emitting surface which emits laser light along a fast and slow axis; and
a reflection means for reflecting light emitted from the emitting surface of the semiconductor laser and within a range of a predetermined angle in the direction of the slow axis to the semiconductor laser, said reflecting means tilted at a tilt angle along the slow axis from a normal to the emitting surface of the semiconductor laser.

2. A semiconductor laser device according to claim 1, wherein the reflection means comprises a plane mirror.

3. A semiconductor laser device according to claim 1, wherein the reflection means comprises one of a concave mirror or a convex mirror.

4. A semiconductor laser device according to claim 1, further comprising an optical means positioned between the emitting surface of the semiconductor and the reflecting means for controlling the divergence of the light emitted from the emitting surface of the semiconductor laser in the direction of the fast axis.

5. A semiconductor laser device according to claim 1, wherein the semiconductor laser comprises a single-stripe multimode oscillation semiconductor laser.

6. A fiber laser according to claim 1, comprising:
a light collecting means to collect the laser light emitted from the semiconductor laser, whose light intensity is amplified by external resonance by the reflection means; and
an optical fiber on which the light collected by the light collecting means is incident.

7. A method for controlling a semiconductor laser, comprising the steps of:
controlling the divergence of light emitted from the semiconductor laser in the direction of the fast axis; and
returning light emitted within a range of a predetermined angle in the direction of the slow axis, among the controlled light, to the semiconductor laser by utilizing a reflecting device without utilizing a focusing lens between the semiconductor laser and the reflecting device.

8. A method for controlling a semiconductor laser, according to claim 7, further comprising the step of collecting the laser light emitted from the semiconductor laser to make it incident on an optical fiber, of which light intensity is amplified by external resonance by returning the light from the reflecting device to the semiconductor laser screen.

9. An image display device comprising:
a semiconductor laser device emitting laser light and including a reflection device to return the laser light emitted within a range of a predetermined angle in the direction of the slow axis, among the laser light emitted from the semiconductor laser, to the semiconductor laser so as to amplify the laser light by external resonance;
an optical fiber excited by the incidence of the light emitted from the semiconductor laser device;
a modulation means to space-modulate the light excited by the optical fiber in accordance with an image signal; and
a display unit to project and display optical light obtained from the modulation device.

10. An image display device according to claim 9, wherein the semiconductor laser device, the optical fiber, and the modulation device are provided for each of the colors red, green and blue; and
wherein the display unit composes the optical light from each of the red, green and blue modulation devices and projects same on a screen of the display device.

11. An image display device according to claim 9, wherein the semiconductor laser device and the optical fiber are provided for each of the colors red, green and blue; and
wherein the modulation devices space-modulates white light in which the optical light from each optical fiber corresponding to thered, green and blue light is collected.

12. A projection TV receiver comprising:
a tuner for tuning a received TV signal;
a signal processor for demodulating an image signal from the TV signal tuned by the tuner;
a semiconductor laser device including a reflection device to return light emitted within a range of a predetermined angle in the direction of the slow axis, among light emitted from the semiconductor laser, to the semiconductor laser;
an optical fiber excited by the incidence of the light emitted from the semiconductor laser device;
a modulation device to space-modulate the light excited by the optical fiber in accordance with an image signal output from the signal processor; and
a display unit to project and display optical light obtained from the modulation device on a display screen.

13. A semiconductor laser device for emitting laser light by external resonance of a semiconductor laser, comprising:
a semiconductor laser of a multimode oscillation type for emitting light at a divergence angle θx about the optical axis (z) from a light emitting area in the direction of the slow axis (x); and
a reflecting mirror of which the reflection plane is inclined substantially at an angle θx with respect to the slow axis (x) so that light emitted from the emitting area of the semiconductor laser is incident on the reflection plane perpendicularly thereto, for reflecting the light emitted from the semiconductor laser to feed back the reflected light to the semiconductor laser, thereby promoting the external resonance of the semiconductor laser.

14. The semiconductor laser device as recited in claim 13 wherein a fast axis collimator is disposed between said emitting area of the semiconductor laser and the reflecting mirror and without utilizing a focusing mirror between said collimator and said reflecting mirror.

15. A semiconductor laser device for emitting laser light by external resonance;
a reflecting mirror having a reflection plan inclined substantially at an angle θx with respect to a slow axis (x) of the semiconductor laser so that the laser light is incident on the reflection plane perpendicularly thereto; and
a semiconductor laser of a multimode oscillation type for emitting light at a divergence angle θx about an optical axis (z) from a light emitting area in the direction of the slow axis (x), on which the light reflected by the reflecting mirror is incident, and emitting light resonant with the incident light by external resonance;
a collecting lens for collecting the resonant light emitted from the semiconductor laser; and
an optical fiber on which the light collected by the collecting lens is incident for performing up-conversion to emit visible light.

16. An image display device using a semiconductor laser device for emitting laser light by external resonance of the semiconductor laser, comprising:
a first reflecting mirror having a reflection plane inclined substantially at an angle θx1 with respect to a slow axis of the semiconductor laser so as to achieve resonance of the semiconductor laser, comprising:
a first semiconductor laser of a multimode oscillation type for emitting light within a divergence angle θx1 about an optical axis (z) from a light emitting area in the direction of the slow axis (x), on which the light reflected by the first reflecting mirror is incident, and emitting first light resonant with the light by external resonance;
a first collecting lens for collecting the first resonant light emitted from the first semiconductor laser; and
a first optical fiber on which the light collected by the first collecting lens is incident for performing first up-conversion to emit first visible light;
a second reflecting mirror having a reflection plane inclined substantially at an angle θx2 with respect to a slow axis of the semiconductor laser so that second laser light is incident on the reflection plane perpendicularly thereto;
a second semiconductor laser of a multimode oscillation type for emitting light within a divergence angle θx2 about an optical axis (z) from a light emitting area in the direction of the slow axis (x), on which the light reflected by the second reflecting mirror is incident, and emitting second light resonant with the light by external resonance;
a second collecting lens for collecting the second resonant light emitted from the second semiconductor laser;
a second optical fiber on which the light collected by the second collecting lens is incident for performing second up-conversion to emit second visible light;
a third reflecting mirror having a reflection plane inclined substantially at an angle θx3 with respect to a slow axis of the semiconductor laser so that third laser light is incident on the reflection plane perpendicularly thereto;
a third semiconductor laser of a multimode oscillation type for emitting light within a divergence angle θx3 about an optical axis (z) from a light emitting area in the direction of the slow axis (x), on which the light reflected by the third reflecting mirror is incident, and emitting third light resonant with the light by external resonance;
a third collecting lens for collecting the third resonant light emitted from the third semiconductor laser;
a third optical fiber on which the light collected by the third collecting lens is incident for performing third up-conversion to emit third visible light; and
a dichroic prism for composing the first visible light, the second visible light, and the third visible light to generate white light.
